(19) United States
(12) Patent Application Publication
(10) Pub. No.: US 2014/0286098 A1
(43) Pub. Date: Sep. 25, 2014

(54) NONVOLATILE SEMICONDUCTOR MEMORY DEVICE

(71) Applicant: Kabushiki Kaisha Toshiba, Minato-ku (JP)

(72) Inventor: Naoki YASUDA, Yokkaichi-shi (JP)

(73) Assignee: Kabushiki Kaisha Toshiba, Minato-ku (JP)

(21) Appl. No.: 14/132,333

(22) Filed: Dec. 18, 2013

(30) Foreign Application Priority Data
Mar. 25, 2013 (JP) 2013-062258

(51) Int. Cl. H01L 27/11; G11C 16/04

(52) U.S. Cl. CPC H01L 27/1104; G11C 16/0466
USPC 365/185.11; 257/324

(57) ABSTRACT

A nonvolatile semiconductor memory device according to an embodiment includes a memory string having a plurality of electrically rewritable memory transistors connected in series therein. The memory string includes a first semiconductor layer including a columnar portion extending in a perpendicular direction to a substrate; a tunnel insulating film formed surrounding a side surface of the columnar portion; a charge storage film formed surrounding the tunnel insulating film; a block insulating film formed surrounding the charge storage film; and a plurality of first conductive layers formed surrounding the block insulating film and disposed with a certain spacing along the perpendicular direction. The charge storage film includes a first charge storage film having a conducting property and located in contact with the tunnel insulating film; and a second charge storage film having an insulating property and formed between the first charge storage film and the block insulating film.

### CROSS REFERENCE TO RELATED APPLICATION

This application is based upon and claims the benefit of priority from Japanese Patent Application No. 2013-062258, filed on Mar. 25, 2013, the entire contents of which are incorporated herein by reference.

### BACKGROUND

1. Field

Embodiments relate to a nonvolatile semiconductor memory device.

2. Description of the Related Art

In order to increase a degree of integration of memory cells, several nonvolatile semiconductor memory devices having the memory cells disposed three-dimensionally (stacked type nonvolatile semiconductor memory devices) have been proposed in recent years. In these stacked type nonvolatile semiconductor memory devices, it is required that during a data erase operation, data can be quickly erased from a large number of the memory cells.

### BRIEF DESCRIPTION OF THE DRAWINGS

FIG. 1 is a block diagram of a semiconductor device according to a first embodiment.

FIG. 2 is a circuit diagram showing a memory block MB according to the first embodiment.

FIG. 3 is a perspective view showing a stacked structure of the memory block MB according to the first embodiment.

FIG. 4 is a cross-sectional view of the memory block MB according to the first embodiment.

FIG. 5 is a cross-sectional view and a top view showing a MONOS type memory cell according to the first embodiment.

FIG. 6 is a view showing an operation of the memory block MB according to the first embodiment.

FIG. 7A is a view showing an operation of the memory block MB according to the first embodiment.

FIG. 7B is a view showing an operation of the memory block MB according to the first embodiment.

FIG. 8 is a view showing energy bands of the MONOS type memory cell according to the first embodiment.

FIG. 9 is a graph showing characteristics of the MONOS type memory cell during an operation according to the first embodiment.

FIG. 10 is a view showing energy bands of the MONOS type memory cell according to the first embodiment.

FIG. 11 is a graph showing characteristics of the MONOS type memory cell during an operation according to the first embodiment.

FIG. 12A is a view showing a method of manufacture of the MONOS type memory cell according to the first embodiment.

FIG. 12B is a view showing the method of manufacture of the MONOS type memory cell according to the first embodiment.

FIG. 12C is a view showing the method of manufacture of the MONOS type memory cell according to the first embodiment.

FIG. 13A is a view showing the method of manufacture of the MONOS type memory cell according to the first embodiment.

FIG. 13B is a view showing the method of manufacture of the MONOS type memory cell according to the first embodiment.

FIG. 13C is a view showing the method of manufacture of the MONOS type memory cell according to the first embodiment.

FIG. 14 is a cross-sectional view showing a MONOS type memory cell according to a second embodiment.

FIG. 15 is a cross-sectional view showing a MONOS type memory cell according to a third embodiment.

FIG. 16 is a cross-sectional view showing a MONOS type memory cell according to a fourth embodiment.

FIG. 17 is a cross-sectional view showing a MONOS type memory cell according to a fifth embodiment.

FIG. 18 is a cross-sectional view showing a MONOS type memory cell according to a sixth embodiment.

### DETAILED DESCRIPTION

A nonvolatile semiconductor memory device according to an embodiment comprises a memory string having a plurality of electrically rewritable memory transistors connected in series therein. The memory string comprises: a first semiconductor layer including a columnar portion extending in a perpendicular direction to a substrate, the first semiconductor layer functioning as a body of the memory transistor; a tunnel insulating film formed surrounding a side surface of the columnar portion; a charge storage film formed surrounding the tunnel insulating film and configured to be capable of storing a charge; a block insulating film formed surrounding the charge storage film; and a plurality of first conductive layers formed surrounding the block insulating film and disposed with a certain spacing along the perpendicular direction. The charge storage film comprises: a first charge storage film having a conducting property and located in contact with the tunnel insulating film; and a second charge storage film having an insulating property and formed between the first charge storage film and the block insulating film.

A semiconductor device according to an embodiment is described below with reference to the drawings.

### First Embodiment

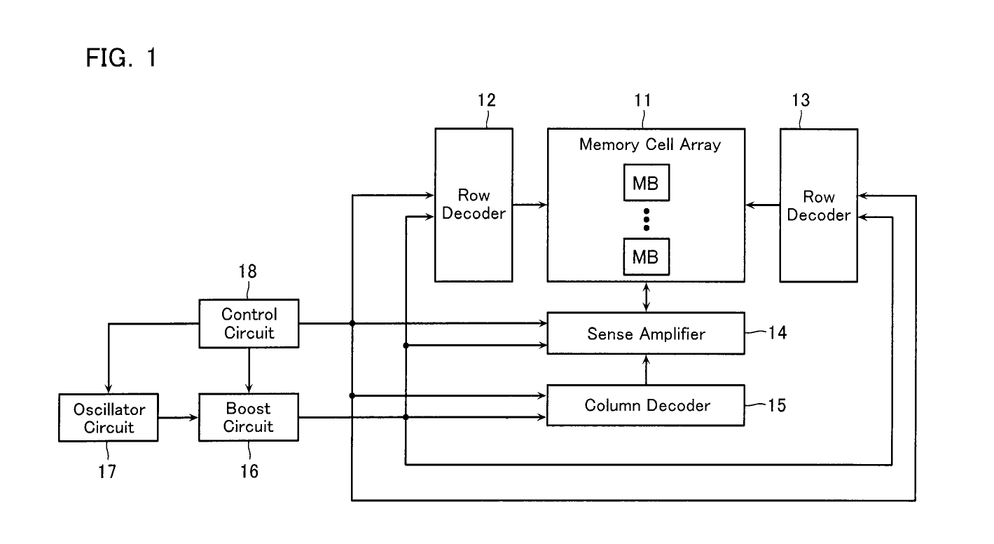

A configuration of a semiconductor device according to a first embodiment is described below. FIG. 1 is a block diagram of the semiconductor device according to the first embodiment.

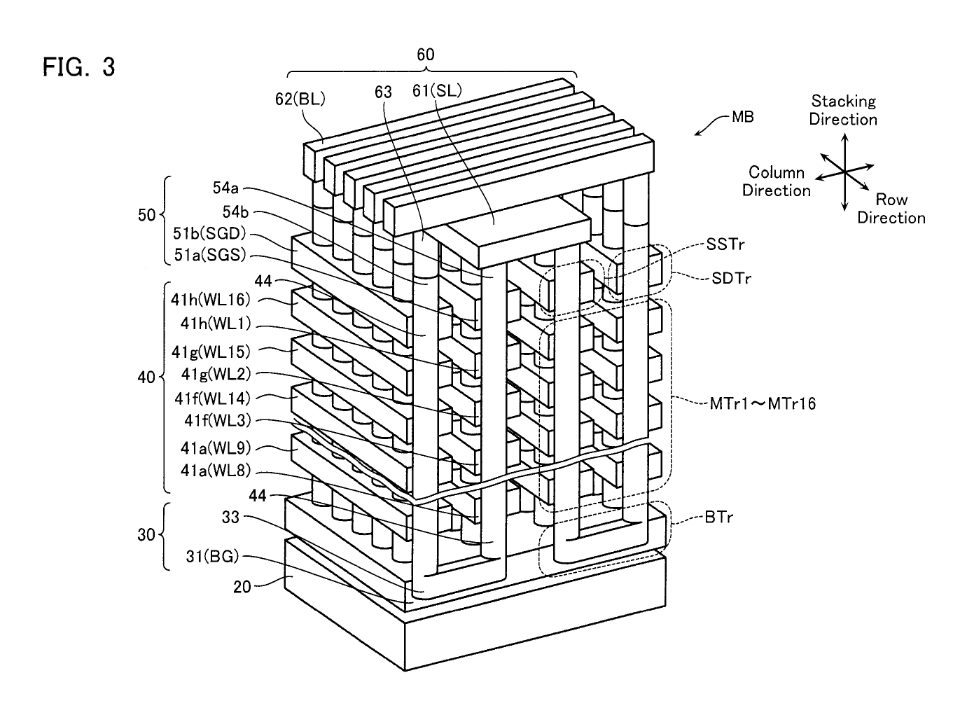

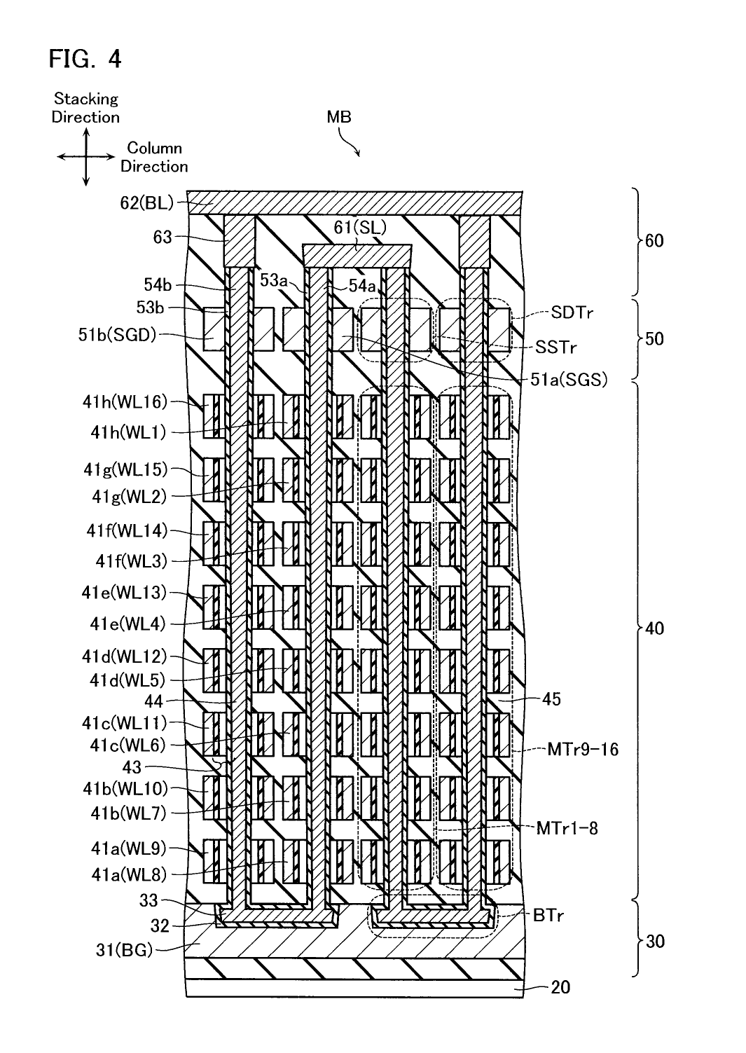

As shown in FIG. 1, the semiconductor device according to the first embodiment includes a memory cell array 11, row decoders 12 and 13, a sense amplifier 14, a column decoder 15, a boost circuit 16, an oscillator circuit 17, and a control circuit 18. The present embodiment configures the memory cell array 11 by a stacked structure shown in later-described FIGS. 3 and 4, thereby reducing an occupied area of the memory cell array 11.

The memory cell array 11 is configured from a plurality of memory blocks MB. The memory block MB configures a minimum erase unit of batch erase when executing a data erase operation.

As shown in FIG. 1, the row decoders 12 and 13 function to decode a row address signal and select a word line. The sense amplifier 14 reads data from the memory cell array 11. The column decoder 15 functions to decode a column address signal and select a bit line.

The boost circuit 16 generates a high voltage required during write or erase, and supplies the high voltage to the row decoders 12 and 13, the sense amplifier 14, and the column decoder 15. The oscillator circuit 17 generates a clock signal and supplies that clock signal to the boost circuit 16. The control circuit 18 controls the row decoders 12 and 13, the sense amplifier 14, the column decoder 15, the boost circuit 16, and the oscillator circuit 17.

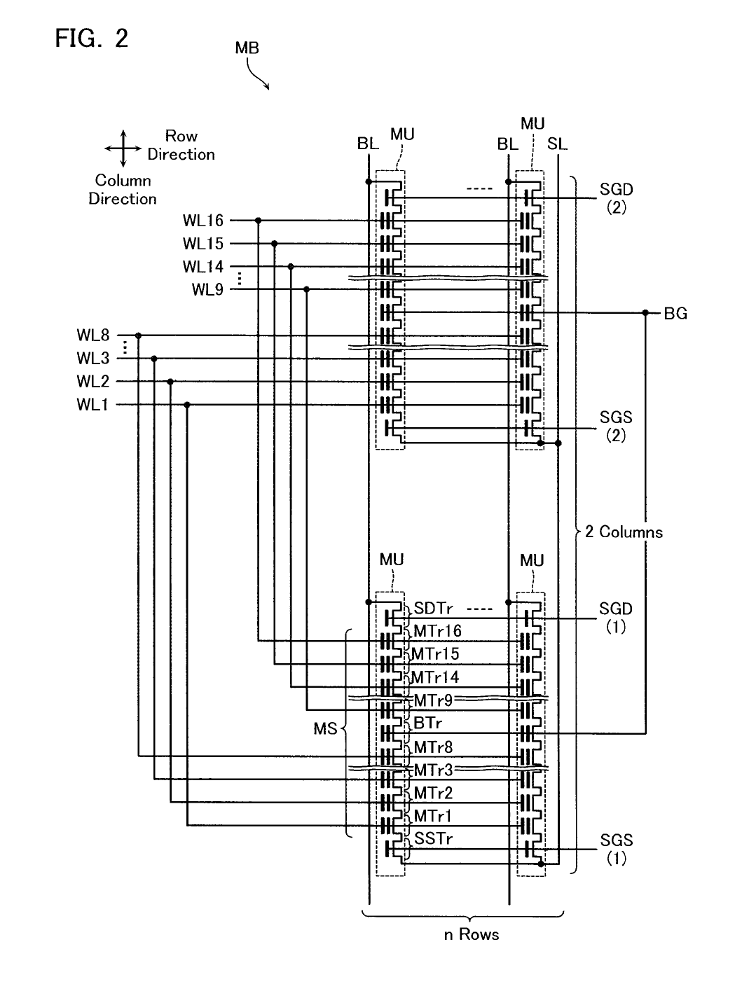

Next, a specific configuration of the memory block MB is described with reference to FIG. 2. As shown in FIG. 2, the memory block MB includes a plurality of bit lines BL, a source line SL, and a plurality of memory units MU connected to these bit lines BL and source line SL.

The memory block MB includes the memory units MU arranged in a matrix of n rows and 2 columns. The configuration of n rows and 2 columns is merely one example, and the memory block MB is not limited to this configuration.

One end of the memory unit MU is connected to the bit line BL, and the other end of the memory unit MU is connected to the source line SL. The plurality of bit lines BL extend in a column direction with a certain pitch in a row direction.

The memory unit MU includes a memory string MS, a source side select transistor SSTr, and a drain side select transistor SDTr.

As shown in FIG. 2, the memory string MS includes memory transistors MTr1˜MTr16 (memory cells) and a back gate transistor BTr connected in series. The memory transistors MTr1˜MTr8 are connected in series to each other, and the memory transistors MTr9˜MTr16 are also connected in series to each other. The back gate transistor BTr is connected between the memory transistor MTr8 and the memory transistor MTr9. Note that as shown in later-described FIG. 3, the memory transistors MTr1˜MTr16 are arranged three-dimensionally in the row direction, the column direction, and a stacking direction (perpendicular direction to a substrate). Note that FIG. 2 is merely one example, and the number of memory transistors in the memory string MS is not limited to 16, and may be more than 16 or less than 16.

The memory transistors MTr1˜MTr16 hold data by storing a charge in a charge storage film of the memory transistors MTr1˜MTr16. The back gate transistor BTr is set to a conductive state at least when the memory string MS is selected as a target of an operation.

Commonly connected to gates of the memory transistors MTr1˜MTr16 arranged in the matrix of n rows and 2 columns in the memory block MB are word lines WL1˜WL16, respectively. Commonly connected to gates of the n rows and 2 columns of back gate transistors BTr is a single back gate line BG.

A drain of the source side select transistor SSTr is connected to a source of the memory string MS. A source of the source side select transistor SSTr is connected to the source line SL. Commonly connected to gates of the n source side select transistors SSTr arranged in a line in the row direction in the memory block MB is a single source side select gate line SGS(1) or SGS(2). Note that below, the source side select gate lines SGS(1) and SGS(2) are also sometimes collectively referred to as source side select gate line SGS, without distinction.

A source of the drain side select transistor SDTr is connected to a drain of the memory string MS. A drain of the drain side select transistor SDTr is connected to the bit line BL. Commonly connected to gates of the n drain side select transistors SDTr arranged in a line in the row direction in each of the memory blocks MB is a drain side select gate line SGD(1) or SGD(2). Note that below, the drain side select gate lines SGD (1) and SGD(2) are also sometimes collectively referred to as drain side select gate line SGD, without distinction.

Next, the stacked structure of the memory block MB is described with reference to FIGS. 3 and 4. As shown in FIGS. 3 and 4, the memory block MB includes a back gate layer 30, a memory layer 40, a select transistor layer 50, and a wiring layer 60 that are stacked sequentially on a substrate 20. The back gate layer 30 functions as the back gate transistor BTr. The memory layer 40 functions as the memory transistors MTr1˜MTr16. The select transistor layer 50 functions as the drain side select transistor SDTr and the source side select transistor SSTr. The wiring layer 60 functions as the source line SL and the bit line BL.

As shown in FIGS. 3 and 4, the back gate layer 30 includes a back gate conductive layer 31. The back gate conductive layer 31 functions as the back gate line BG and as the gate of the back gate transistor BTr. The back gate conductive layer 31 is formed extending in a plate-like shape two-dimensionally in the row direction and the column direction parallel to the substrate 20. The back gate conductive layer 31 is configured by polysilicon (poly-Si), for example.

As shown in FIGS. 3 and 4, the back gate layer 30 includes aback gate insulating layer 32 and a back gate semiconductor layer 33.

The back gate insulating layer 32 is configured capable of storing a charge. The back gate insulating layer 32 is provided between the back gate semiconductor layer 33 and the back gate conductive layer 31. The back gate insulating layer 32 is configured by a stacked structure of silicon oxide (SiO₂), silicon nitride (SiN), and silicon oxide (SiO₂), for example.

The back gate semiconductor layer 33 functions as a body (channel) of the back gate transistor BTr. The back gate semiconductor layer 33 is formed digging into the back gate conductive layer 31. The back gate semiconductor layer 33 is configured by polysilicon (poly-Si), for example.

As shown in FIGS. 3 and 4, the memory layer 40 is formed in a layer above the back gate layer 30. The memory layer 40 includes eight layers of word line conductive layers 41a˜41h. The word line conductive layer 41a functions as the word line WL8 and as the gate of the memory transistor MTr8. Moreover, the word line conductive layer 41a functions also as the word line WL9 and as the gate of the memory transistor MTr9. Similarly, the word line conductive layers 41b˜41h function as the word lines WL7˜WL1 and as the gates of the memory transistors MTr7˜MTr1, respectively. Moreover, the word line conductive layers 41b˜41h function also as the word lines WL10˜WL16 and as the gates of the memory transistors MTr10˜MTr16, respectively.

The word line conductive layers 41a˜41h are stacked sandwiching an interlayer insulating layer 45 between each of the word line conductive layers 41a˜41h, above and below. As a result, the word line conductive layers 41a˜41h are disposed with a certain spacing along the stacking direction (perpendicular direction to the substrate). The word line conductive layers 41a˜41h extend having the row direction (direction perpendicular to a plane of paper in FIG. 4) as a long direction. The word line conductive layers 41a˜41h are configured by polysilicon (poly-Si), for example.

As shown in FIGS. 3 and 4, the memory layer 40 includes a memory gate insulating layer 43 and a memory columnar semiconductor layer 44.

The memory gate insulating layer 43 is configured capable of storing a charge. The memory gate insulating layer 43 is provided between the memory columnar semiconductor layer 44 and the word line conductive layers 41a˜41h. The memory gate insulating layer 43 includes a stacked structure of silicon oxide (SiO₂), silicon nitride (SiN), and silicon oxide (SiO₂), for example. In the semiconductor memory device of the present embodiment, an ONO (Oxide-Nitride-Oxide) layer is provided around the memory columnar semiconductor layer 44 to configure a MONOS type memory cell. Note that a detailed stacked structure of the memory gate insulating layer 43 is described fully later.

The memory columnar semiconductor layer 44 functions as bodies (channels) of the memory transistors MTr1˜MTr16. The memory columnar semiconductor layer 44 extends in the perpendicular direction to the substrate 20, penetrating the word line conductive layers 41a˜41h and the interlayer insulating layer 45. A pair of the memory columnar semiconductor layers 44 are formed to align with a close vicinity of ends in the column direction of one back gate semiconductor layer 33. The memory columnar semiconductor layer 44 is configured by polysilicon (poly-Si), for example.

In the above-described back gate layer 30 and memory layer 40, the pair of memory columnar semiconductor layers 44 and the back gate semiconductor layer 33 joining lower ends of the pair of memory columnar semiconductor layers 44 function as a body (channel) of the memory string MS, and are formed in a U shape as viewed from the row direction.

Expressing the above-described configuration of the back gate layer 30 in other words, the back gate conductive layer 31 surrounds side surfaces and a lower surface of the back gate semiconductor layer 33 via the back gate insulating layer 32. Moreover, expressing the above-described configuration of the memory layer 40 in other words, the word line conductive layers 41a˜41h surround a side surface of the memory columnar semiconductor layer 44 via the memory gate insulating layer 43.

As shown in FIGS. 3 and 4, the select transistor layer 50 includes a source side conductive layer 51a and a drain side conductive layer 51b. The source side conductive layer 51a functions as the source side select gate line SGS and as the gate of the source side select transistor SSTr. The drain side conductive layer 51b functions as the drain side select gate line SGD and as the gate of the drain side select transistor SDTr.

The source side conductive layer 51a is formed in a layer above one of a pair of the memory columnar semiconductor layers 44. The drain side conductive layer 51b is in the same layer as the source side conductive layer 51a and formed in a layer above the other of a pair of the memory columnar semiconductor layers 44. A plurality of the source side conductive layers 51a and drain side conductive layers 51b are formed extending in the row direction with a certain pitch in the column direction. The source side conductive layer 51a and the drain side conductive layer 51b are configured by polysilicon (poly-Si), for example.

As shown in FIGS. 3 and 4, the select transistor layer 50 includes a source side gate insulating layer 53a, a source side columnar semiconductor layer 54a, a drain side gate insulating layer 53b, and a drain side columnar semiconductor layer 54b. The source side columnar semiconductor layer 54a functions as a body (channel) of the source side select transistor SSTr. The drain side columnar semiconductor layer 54b functions as a body (channel) of the drain side select transistor SDTr.

The source side gate insulating layer 53a is provided between the source side conductive layer 51a and the source side columnar semiconductor layer 54a. The source side gate insulating layer 53a is configured by silicon oxide (SiO₂), for example. The source side columnar semiconductor layer 54a extends in the perpendicular direction to the substrate 20, penetrating the source side conductive layer 51a. The source side columnar semiconductor layer 54a is connected to a side surface of the source side gate insulating layer 53a and to an end of one of a pair of the memory columnar semiconductor layers 44. The source side columnar semiconductor layer 54a is configured by polysilicon (poly-Si), for example.

The drain side gate insulating layer 53b is provided between the drain side conductive layer 51b and the drain side columnar semiconductor layer 54b. The drain side gate insulating layer 53b is configured by silicon oxide (SiO₂), for example. The drain side columnar semiconductor layer 54b extends in the perpendicular direction to the substrate 20, penetrating the drain side conductive layer 51b. The drain side columnar semiconductor layer 54b is connected to a side surface of the drain side gate insulating layer 53b and to an end of the other of a pair of the memory columnar semiconductor layers 44. The drain side columnar semiconductor layer 54b is configured by polysilicon (poly-Si), for example.

The wiring layer 60 includes a source line layer 61, a bit line layer 62, and a plug layer 63. The source line layer 61 functions as the source line SL, and the bit line layer 62 functions as the bit line BL.

The source line layer 61 extends in the row direction, contacting an upper surface of the source side columnar semiconductor layer 54a. The bit line layer 62 extends in the column direction, contacting an upper surface of the drain side columnar semiconductor layer 54b via the plug layer 63. The source line layer 61, the bit line layer 62, and the plug layer 63 are configured by a metal such as tungsten, for example.

[Structure of MONOS Type Memory Cell]

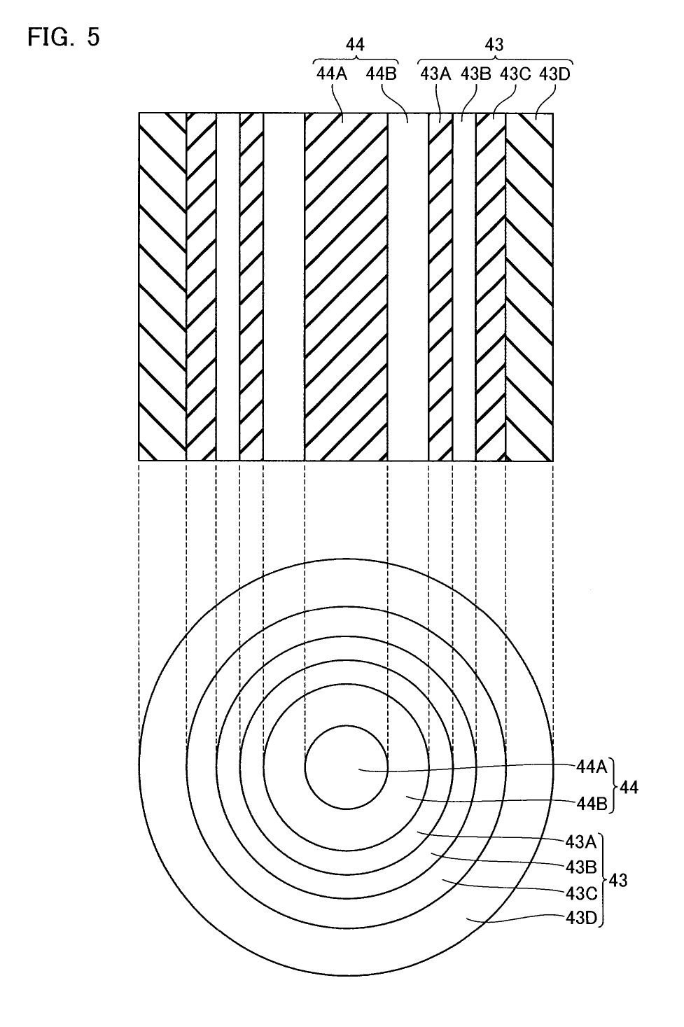

Next, the memory transistor MTr (memory cell) in the nonvolatile semiconductor memory device according to the first embodiment is described using FIG. 5. The detailed stacked structure of the memory gate insulating layer 43 provided to the memory layer 40 is described below.

FIG. 5 is a cross-sectional view and a top view showing a MONOS type memory cell according to the first embodiment. More specifically, the upper portion of FIG. 5 shows a cross-sectional view of the MONOS type memory cell according to the first embodiment, and the lower portion of FIG. 5 shows a planar view of same MONOS type memory cell. Note that FIG. 5 is a view representing the MONOS type memory cell schematically, and that actual dimensions are sometimes different from a state indicated in FIG. 5. FIG. 5 shows a state of the memory gate insulating layer 43 and the memory columnar semiconductor layer 44, and omits the word line conductive layer 41 functioning as the gate.

As shown in FIG. 5, the MONOS type memory cell comprises the memory columnar semiconductor layer 44 and the memory gate insulating layer 43 formed in a cylindrical shape. The memory columnar semiconductor layer 44 includes a core layer 44A formed by for example silicon oxide (SiO₂), and a channel layer 44B formed by for example silicon (Si) and functioning as a body (channel) of the memory transistor MTr.

The memory gate insulating layer 43 comprises a tunnel insulating film 43A, a first charge storage film 43B, a second charge storage film 43C, and a block insulating film 43D.

The tunnel insulating film 43A is formed surrounding a side surface of the channel layer 44B. The tunnel insulating film 43A is configured by silicon oxide (SiO₂), for example. The tunnel insulating film 43A, as well as being a single layer film of silicon oxide (SiO₂), may also be a stacked film (for example, an ONO tunnel film).

The first charge storage film 43B is formed surrounding a side surface of the tunnel insulating film 43A. The first charge storage film 43B according to the present embodiment is configured by a material such as polysilicon (poly-Si), for example, that has a band gap which is smaller than that of the later-described second charge storage film 43C. The first charge storage film 43B may be insulated along the direction perpendicular to the substrate to correspond with the word line conductive layers 41 of each of the memory transistors MTr.

The second charge storage film 43C is formed surrounding a side surface of the first charge storage film 43B. The second charge storage film 43C is configured by silicon nitride (SiN), for example. Moreover, the second charge storage film 43C is not limited to silicon nitride (SiN), and may be configured by various kinds of insulating films capable of storing a charge and configured by a material that has a band gap which is larger than that of the first charge storage film 43B.

The block insulating film 43D is formed surrounding a side surface of the second charge storage film 43C. Although omitted from FIG. 5, formed on a side surface of the block insulating film 43D is the word line conductive layer 41 that functions as the gate of the memory cell. The block insulating film 43D is configured by silicon oxide (SiO₂), for example. Moreover, the block insulating film 43D is not limited to this, and may be configured by a stacked film of SiO₂ or silicon nitride (SiN).

These memory gate insulating layer 43 and memory columnar semiconductor layer 44 are formed along a cylindrical memory hole, hence are each formed in a cylindrical shape. In addition, the memory gate insulating layer 43 and the memory columnar semiconductor layer 44 are formed concentrically in the memory hole. A diameter of the memory hole is for example 70 nm, and a film thickness of the channel layer 44B is for example 7 nm. Moreover, regarding a film thickness of each layer of the memory gate insulating layer 43, that of the tunnel insulating film 43A is set to 4 nm, that of the first charge storage film. 43B is set to 4 nm, that of the second charge storage film 43C is set to 5 nm, and that of the block insulating film 43D is set to 8 nm. These film thicknesses are illustrative examples, and may be changed arbitrarily according to performance required of the memory transistor MTr. Note that the first charge storage film 43B is formed thinner than the second charge storage film 43C, and is formed with a thickness (for example, 5 nm or less) that enables electrons injected into the first charge storage film 43B from the channel layer 44B via the tunnel insulating film 43A during a later-described write operation to reach the second charge storage film 43C.

[Erase Operation]

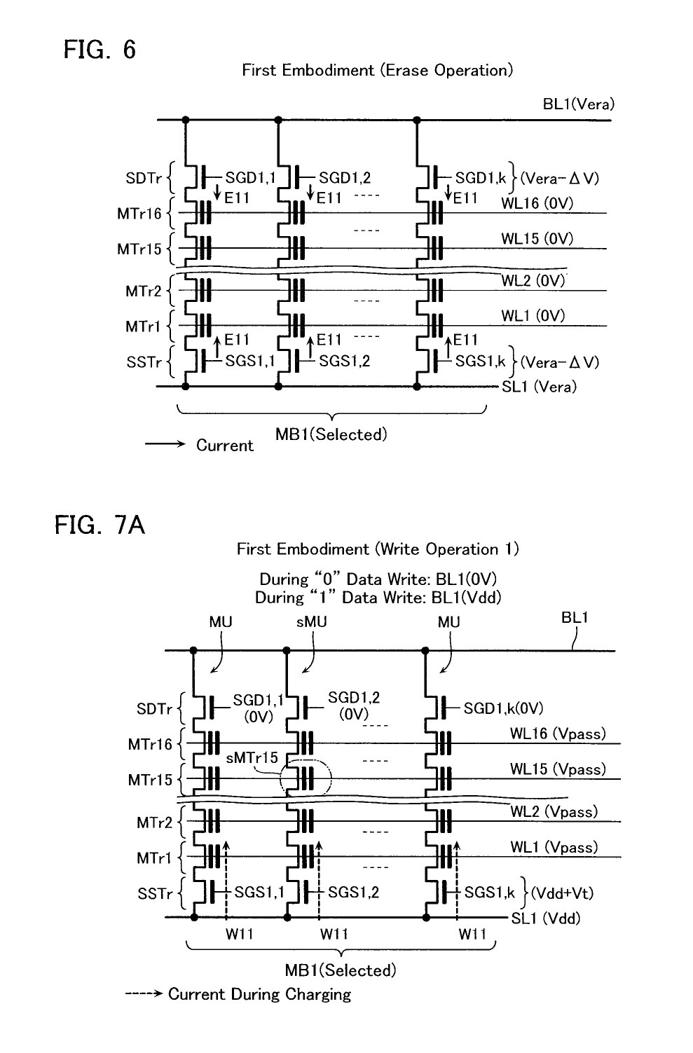

Next, a first erase operation of the nonvolatile semiconductor memory device according to the first embodiment is described with reference to FIG. 6. FIG. 6 shows a memory block MB1 which is part of the memory block MB shown in FIGS. 2˜4. In FIG. 6, the memory block MB1 is illustrated omitting a portion of the memory transistors MTr and the back gate transistor BTr in the memory string MS. In the example shown in FIG. 6, the memory block MB1 is assumed to be selected as a target of the erase operation.

During the erase operation, the bit line BL is applied with a voltage Vera (for example, about 20 V). In the selected memory block MB1, the source line SL1 is applied with the voltage Vera, while the drain side select gate line SGD and the source side select gate line SGS are applied with a voltage Vera-ΔV which is smaller than the voltage Vera by ΔV (for example, about 2 V).

Specifically, as shown in FIG. 6, in the selected memory block MB1, the voltage Vera of the bit line BL1 is higher than the voltage Vera-ΔV of the gate of the drain side select transistor SDTr by an amount of a voltage ΔV. Moreover, the voltage Vera of the source line SL1 is higher than the voltage Vera-ΔV of the gate of the source side select transistor SSTr by an amount of the voltage ΔV. As a result, in the memory block MB1, a GIDL current (refer to symbol “E11”) occurs in a close vicinity of the gate of the source side select transistor SSTr and the drain side select transistor SDTr. Moreover, in the memory block MB1, holes generated by the GIDL current flow into the bodies of the memory transistors MTr1˜MTr16, whereby a voltage of the bodies of the memory transistors MTr1˜MTr16 rises.

Then, a voltage of the gates of the memory transistors MTr1˜MTr16 is set to 0 V, and is thereby set lower than the voltage of the bodies of the memory transistors MTr1˜MTr16. As a result, the memory gate insulating layer 43 of the memory transistors MTr1˜MTr16 is applied with a high voltage, whereby the erase operation on the memory block MB1 is executed.

At this time, the holes generated by the GIDL current at the close vicinity of the gate of the source side select transistor SSTr and the drain side select transistor SDTr are injected into the second charge storage film 43C from the channel layer 44B via the first charge storage film 43B. As a result, electrons trapped in the second charge storage film 43C and the injected holes recombine to be erased.

Moreover, in addition to erase of electrons due to recombination between the holes and electrons, a portion of the electrons trapped in the second charge storage film 43C, after being emitted to the first charge storage film 43B, pass through the tunnel insulating film 43A to flow into the channel layer 44B. This flow of electrons also results in electrons trapped in the second charge storage film 43C being erased. In this way, in the memory transistor MTr of the present embodiment, erase of electrons trapped in the second charge storage film 43C is performed by both injection of holes and flow of electrons.

[Write Operation]

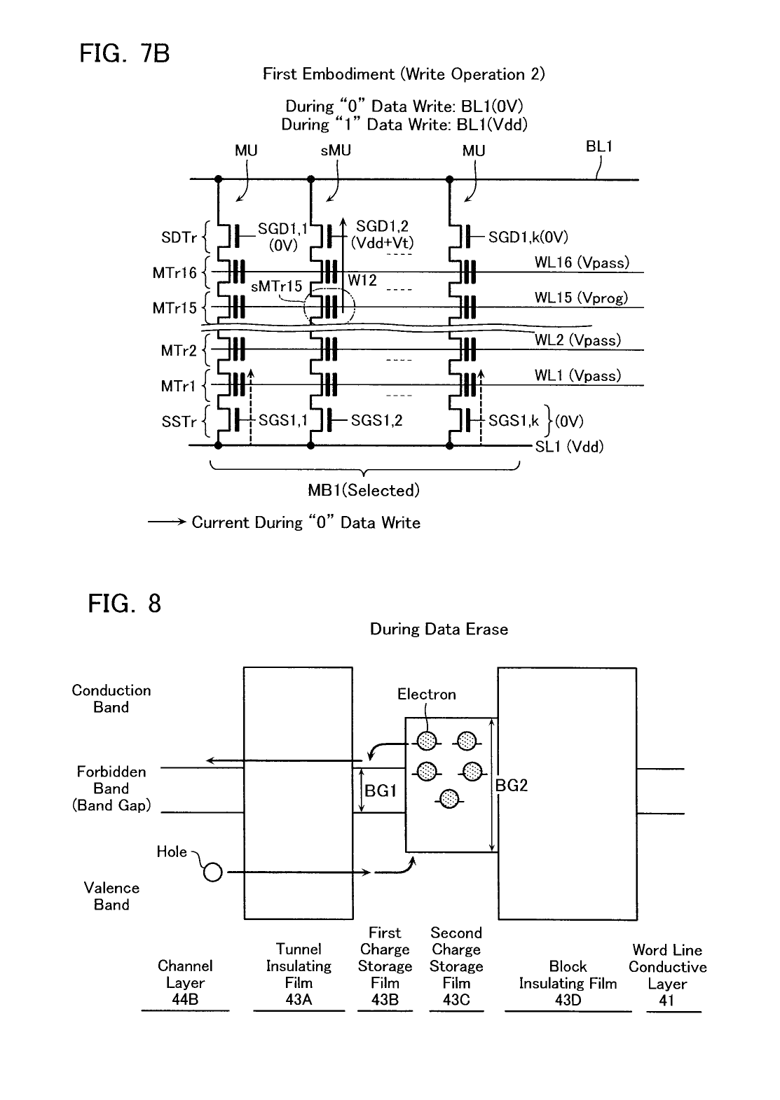

Next, a first write operation of the nonvolatile semiconductor memory device according to the first embodiment is described with reference to FIGS. 7A and 7B.

Described in FIGS. 7A and 7B as an example is the case where a cell unit MU (referred to below as “selected cell unit sMU) in the memory block MB1 is assumed to be a write target. Description proceeds assuming that write is performed on the memory transistor MTr15 (referred to below as “selected memory transistor sMTr15) in the selected cell unit sMU.

Specifically, as shown in FIG. 7A, first, when writing data of the selected memory transistor sMTr15 with “0” data, a voltage of the bit line BL1 is set to 0 V, and, when holding data of the selected memory transistor sMTr15 at “1” data, the voltage of the bit line BL1 is set to a power supply voltage Vdd (for example, 1.2 V). The source line SL1 is set to the power supply voltage Vdd.

Then, the memory transistors MTr1˜MTr16 included in the memory block MB1 have their gates applied with a pass voltage Vpass (for example, 10 V) to be set to a conductive state. The source side select transistor SSTr has its gate applied with a voltage Vdd+Vt to be set to a conductive state. As a result, a voltage of the bodies of the memory transistors MTr1˜MTr16 included in the memory block MB1 is charged to the power supply voltage Vdd via the source line SL1 (refer to symbol “W11”). That is, the voltage of the bodies of the memory transistors MTr1˜MTr16 included in the memory block MB1 is set greater than or equal to the voltage Vdd able to be applied to the bit line BL1 during the write operation. Moreover, after a certain time, the source side select transistor SSTr is set again to a non-conductive state.

Next, as shown in FIG. 7B, the drain side select transistor SDTr included in the selected cell unit sMU has its gate supplied with the voltage Vdd+Vt. When the bit line BL1 is being supplied with 0 V to write “0” data, the drain side select transistor SDTr attains a conductive state, whereby the voltage of the bodies of the memory transistors MTr1˜MTr16 included in the selected cell unit sMU is discharged to the same 0 V as the bit line BL1 (refer to symbol “W12”). On the other hand, when the bit line BL1 is being supplied with the power supply voltage Vdd to hold at “1” data, the drain side select transistor SDTr remains unchanged in a non-conductive state. Therefore, the bodies of the memory transistors MTr1˜MTr16 included in the selected cell unit sMU are set to a floating state without being discharged and have their potential held at the power supply voltage Vdd.

The drain side select transistor SDTr included in an unselected cell unit MU has its gate supplied with a voltage 0 V to remain unchanged set in a non-conductive state. Therefore, the bodies of the memory transistors MTr1˜MTr16 included in the unselected cell unit MU also have their potential held at the power supply voltage Vdd.

Then, a voltage of the gate of the selected memory transistor sMTr15 is set to a program voltage Vprog (=18 V). As a result, in the case of writing “0” data, the voltage of the body of the selected memory transistor sMTr15 is discharged to 0 V, hence the memory gate insulating layer 43 of the selected memory transistor sMTr15 is applied with a high voltage, whereby the write operation on the selected memory transistor sMTr15 is executed. On the other hand, in the case of holding at “1” data, the body of the selected memory transistor sMTr15 is set to a floating state, hence its potential rises by coupling from the power supply voltage Vdd. As a result, the memory gate insulating layer 43 of the selected memory transistor sMTr15 is not applied with a high voltage, and the write operation on the selected memory transistor sMTr15 is not executed.

Now, the gates of the memory transistors MTr1˜MTr16 along a plurality of the memory units MU are commonly connected by the word lines WL1˜WL16. If the voltage of the gate of the selected memory transistor sMTr15 is assumed to be the program voltage Vprog, then the gate of the memory transistor MTr15 included in a memory unit MU set unselected is also applied with the program voltage Vprog. However, the voltage of the bodies of the memory transistors MTr1˜MTr16 included in the unselected memory unit MU is set to a floating state due to the drain side select transistor SDTr and the source side select transistor SSTr that are set to a non-conductive state. Accordingly, the memory gate insulating layer 43 of the memory transistor MTr15 included in the unselected memory unit MU is not applied with a high voltage, and the write operation is not executed.

[Advantages]

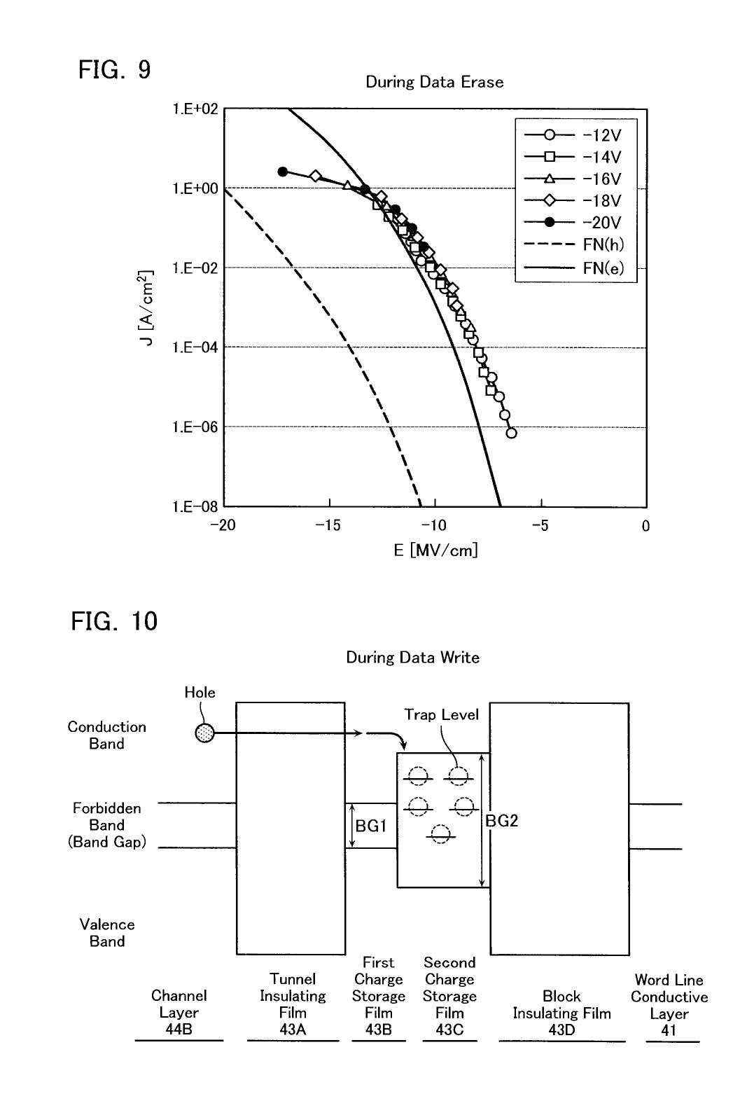

Next, advantages of the nonvolatile semiconductor memory device according to the present embodiment are described. FIGS. 8 and 9 are views showing energy bands during erase and during write of the MONOS type memory cell according to the first embodiment. Note that FIGS. 8 and 9 are views representing the energy bands schematically, and that an electric field acts on the memory cell during an actual operation, hence an actual state would be different from a state indicated in FIGS. 8 and 9.

Formed at an interface between the tunnel insulating film 43A and the second charge storage film 43C according to the first embodiment is the first charge storage film 43B configured from polysilicon. Introducing the first charge storage film 43B configured from polysilicon in this way enables a band structure of the memory gate insulating layer 43 to be modulated. More specifically, as shown in FIGS. 8 and 9, a band gap BG1 of the first charge storage film 43B is smaller than a band gap BG2 of the second charge storage film 43C.

[Advantages During Erase Operation]

As shown in FIG. 8, when a voltage is applied during the erase operation in the MONOS type memory transistor MTr, the holes generated by the GIDL current are injected into the second charge storage film 43C from the channel layer 44B via the tunnel insulating film 43A and the first charge storage film 43B. As a result, those of the electrons trapped in the second charge storage film 43C that are trapped in a deep level and the injected holes recombine to be erased.

Furthermore, in the memory transistor MTr of the present embodiment, a portion of the electrons trapped in the second charge storage film 43C, after being emitted to the first charge storage film 43B, pass through the tunnel insulating film 43A to flow into the channel layer 44B. Due to an erase voltage application, electrons trapped in a high level internally in the second charge storage film 43C are first emitted to a conduction band of the first charge storage film 43B. The first charge storage film 43B is positioned closer to the center of the memory holes than the second charge storage film 43C, and has its electric field concentrated. Hence electrons that have shifted to the first charge storage film 43B are emitted to the channel layer 44B more easily than when present in the second charge storage film 43C. Electrons emitted to the first charge storage film 43B during this erase voltage application are more numerous than electrons erased by the holes.

In this way, in the memory transistor MTr of the present embodiment, erase of electrons trapped in the second charge storage film 43C is performed by both injection of holes and flow of electrons. As a result, compared to the case of executing an erase operation only by injection of holes in a memory cell not provided with the first charge storage film 43B, time required for the erase operation can be reduced, and a contribution to improved erase characteristics can be made.

FIG. 9 is a graph showing a relationship between electric field intensity E and current density J during erase of the MONOS type memory cell according to the first embodiment. FIG. 9 shows a broken line FN (h) indicating a theoretical value in the case where FN current caused by holes has occurred, and a solid line FN (e) indicating a theoretical value in the case where FN current caused by electrons has occurred. In addition, FIG. 9 shows by its symbols the relationship between electric field intensity E and current density J in the cases where an erase voltage Vera having values in the range of −12 V and −20 V is actually applied to the memory transistor MTr.

As shown in FIG. 9, it can be confirmed that during erase of the MONOS type memory cell according to the first embodiment, a current caused by electrons has occurred. Moreover, during the erase operation, a value of the current density at an equal electric field intensity is larger for a current caused by electrons than for a current caused by holes. Introducing the first charge storage film 43B configured from polysilicon at an interface between the tunnel insulating film 43A and the second charge storage film 43C makes it possible for an electron current of large value to be generated during an operation (particularly during an erase operation), whereby speed of the erase operation can be improved compared to the case of executing an erase operation only by injection of holes.

[Advantages During Write Operation]

Moreover, as shown in FIG. 10, during the write operation, electrons pass through the tunnel insulating film 43A in the direction of the first charge storage film 43B. Now, the first charge storage film 43B is set to a film thickness (for example, 5 nm or less) such as to allow electrons injected into the first charge storage film 43B from the channel layer 44B via the tunnel insulating film 43A to reach the second charge storage film 43C. Therefore, the injected electrons pass through the first charge storage film 43B to be trapped in a trap level in the second charge storage film 43C near an interface between the first charge storage film 43B and the second charge storage film 43C. This second charge storage film 43C is further from a central portion of the memory hole by an amount of the film thickness of the first charge storage film 43B whereby an electric field is relaxed during write, hence efficiency of trapping electrons to the second charge storage film 43C during write is improved. It therefore becomes possible to increase a write threshold voltage.

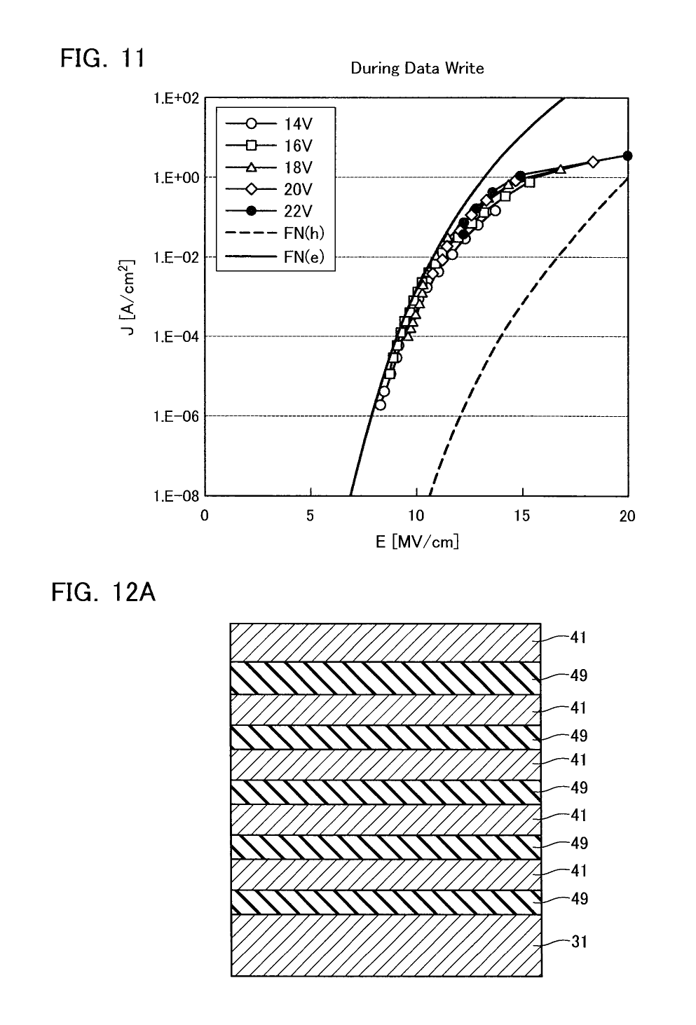

FIG. 11 is a graph showing a relationship between electric field intensity E and current density J during write of the MONOS type memory cell according to the first embodiment. FIG. 11 shows a broken line FN(h) indicating a theoretical value in the case where FN current caused by holes has occurred, and a solid line FN(e) indicating a theoretical value in the case where FN current caused by electrons has occurred. In addition, FIG. 11 shows by its symbols the relationship between electric field intensity E and current density J in the cases where a write voltage Vprog in the range of 14 V and 22 V is actually applied to the memory transistor MTr. It can also be confirmed that during this write operation, similarly to during the erase operation, a current caused by electrons is flowing.

[Method of Manufacture]

Next, a method of manufacture of the MONOS type memory cell according to the first embodiment is described.

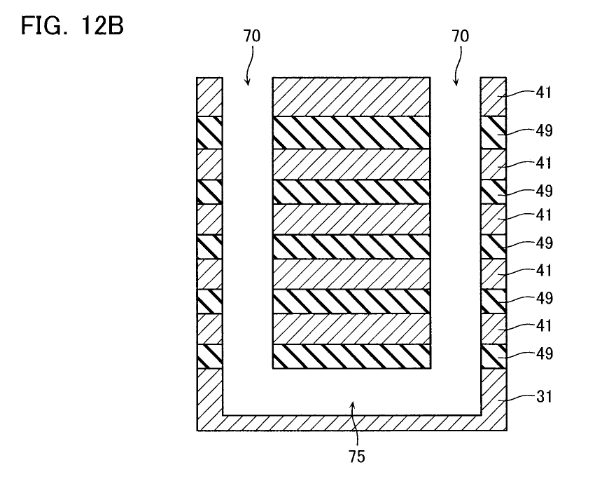

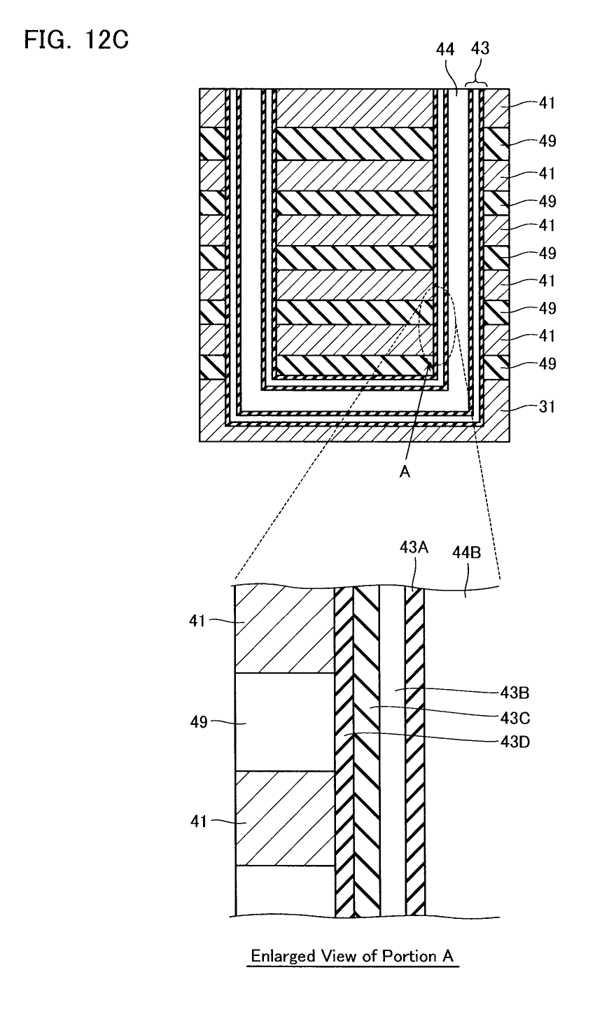

FIGS. 12A˜13C are cross-sectional schematic views for explaining a process of manufacture of the nonvolatile semiconductor memory device according to the first embodiment. FIGS. 12C˜13C show partial enlarged views in addition to the cross-sectional schematic views.

First, as shown in FIG. 12A, the back gate conductive layer 31 including an impurity element is formed on a base layer which is not illustrated. Next, sacrifice layers 49 and the word line conductive layers 41 are stacked alternately on the back gate conductive layer 31.

Next, as shown in FIG. 12B, a pair of holes 70 reaching from a surface of the word line conductive layer 41 to the back gate conductive layer 31, and a hole 75 linked to each of the pair of holes 70 at the back gate conductive layer 31, are formed. The pair of holes 70 are formed by removing the word line conductive layers 41, the sacrifice layers 49, and the back gate conductive layer 31 based on a mask pattern provided on the surface of the word line conductive layer 41, by means of dry etching such as RIE. The hole 75 linked to each of the pair of holes 70 is formed by dissolving a sacrifice layer previously provided to the back gate conductive layer 31, by means of a hot phosphoric acid solution.

Next, as shown in FIG. 12C, the memory gate insulating layer 43 is formed on side walls of each of the pair of holes 70 and the hole 75. Furthermore, the memory columnar semiconductor layer 44 is formed on an inner side of the memory gate insulating layer 43. That is, the block insulating film 43D, the second charge storage film 43C, the first charge storage film 43B, the tunnel insulating film 43A, and the memory columnar semiconductor layer 44 (including the core layer 44A and the channel layer 44B, although the core layer 44A is omitted from FIG. 12C) are formed in this order from the side walls of the pair of holes 70 and the hole 75.

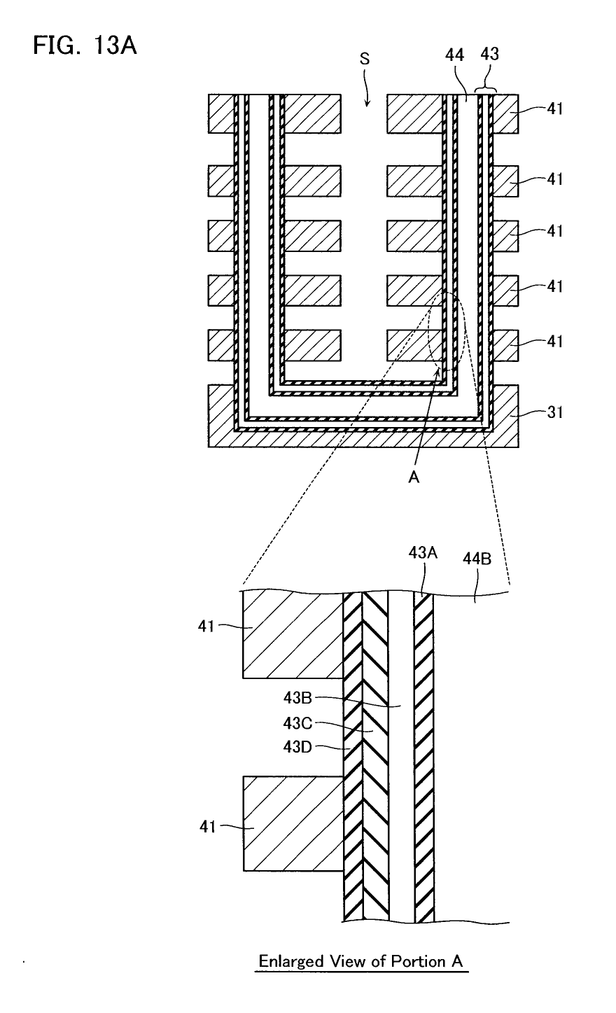

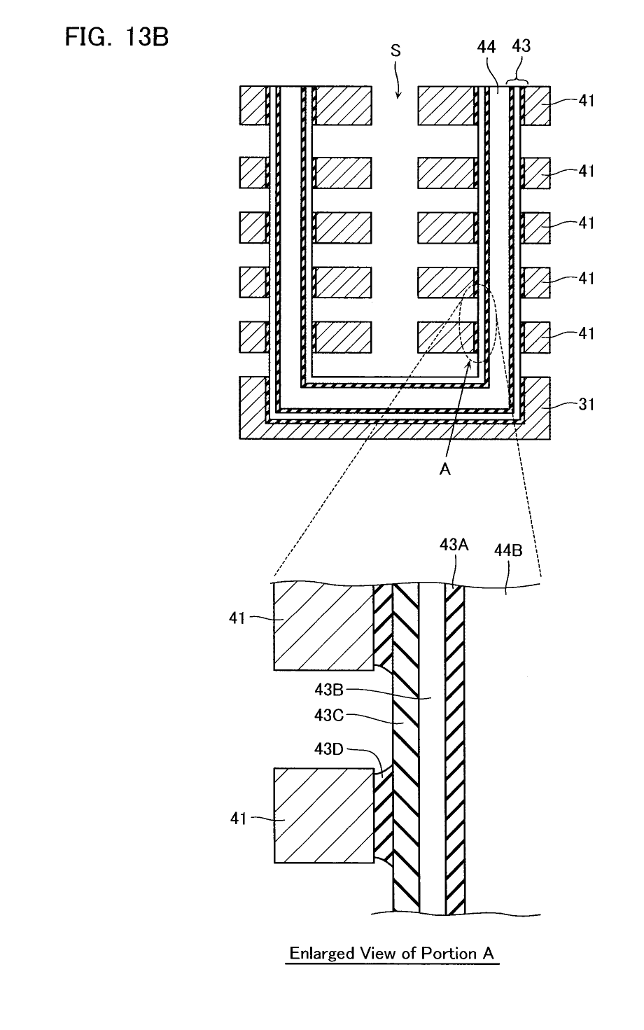

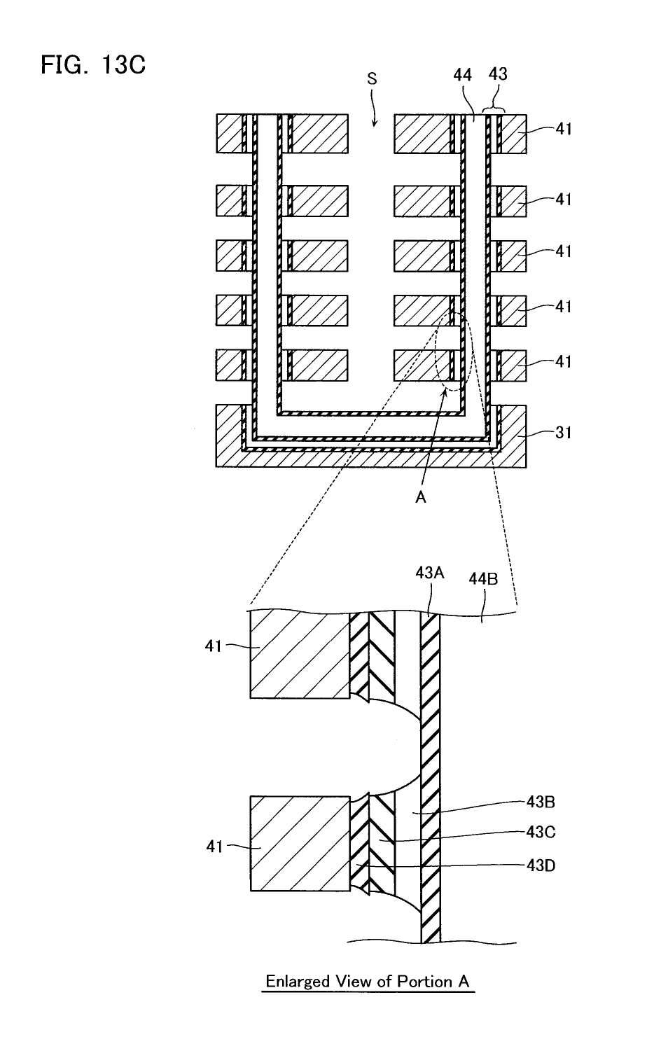

Next, as shown in FIG. 13A, a slit S is formed from the surface of the word line conductive layer 41. Then, the sacrifice layers 49 are removed via the slit S. Removal of the sacrifice layers 49 is performed by for example dissolving the sacrifice layers 49 by an alkaline solution.

Next, as shown in FIG. 13B, the block insulating film 43D between the word line conductive layers 41 is removed. This portion of the block insulating film 43D is removed by for example exposing dilute hydrofluoric acid solution to the block insulating film 43D.

Next, as shown in FIG. 13C, the first charge storage film 43B and the second charge storage film 43C are removed by for example being exposed to an alkaline aqueous solution. As a result, the first charge storage films 43B are insulated along the direction perpendicular to the substrate, corresponding to the word line conductive layers 41 of each of the memory transistors MTr. In the first embodiment, the first charge storage film 43B is formed by polysilicon having conductivity, hence there is a possibility that if the first charge storage film 43B is formed with filling the gap between each memory transistor MTr, a charge accumulated in the first charge storage film 43B will diffuse, thereby causing a problem in an operation. In order to handle this, it is desirable that the first charge storage film 43B is cut off and disposed only in the portions corresponding to the word line conductive layers 41. This is because in that case the charge accumulated in the first charge storage film 43B does not diffuse in the direction perpendicular to the substrate, and data retention characteristics of the memory transistor MTr can be maintained in a good state.

Subsequently, through well-known processes, the insulating layer 45 is formed in the slit S and a structure of an upper portion of the memory string MS such as the source side select transistor, SSTr, the drain side select transistor SDTr, and so on, is formed, thereby forming the nonvolatile semiconductor memory device 1.

### Second Through Sixth Embodiments

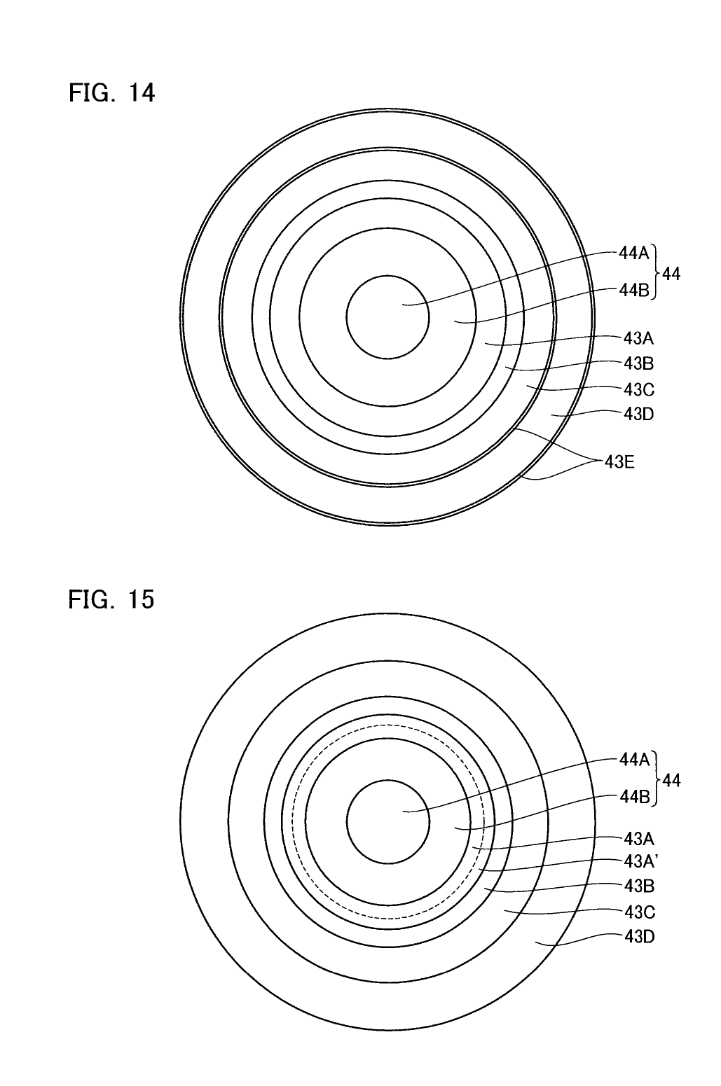

Next, second through sixth embodiments of the present invention are described with reference to FIGS. 14˜18. An overall configuration of the semiconductor memory device in the second through sixth embodiments is similar to that in the first embodiment, hence a detailed description thereof is omitted. In addition, places having a configuration similar to in the first embodiment are assigned with symbols identical to those assigned in the first embodiment, and a duplicated description of such places is omitted. The above-described first embodiment had a first charge storage film 43B formed at an interface between the tunnel insulating film 43A and the second charge storage film 43C. The embodiments below describe configurations where various kinds of films are provided in the memory transistor MTr in addition to the first charge storage film 43B.

### Second Embodiment

FIG. 14 is a cross-sectional view showing a MONOS type memory cell according to the second embodiment. In the memory transistor MTr of the present embodiment, a high-dielectric constant insulating film (high-k film) 43E is provided between the second charge storage film 43C and the block insulating film 43D and between the block insulating film 43D and the word line conductive layer 41 (not illustrated). This high-dielectric constant insulating film 43E is formed by for example alumina (Al₂O₃) and has a film thickness set at about 0.5 nm.

In addition, a diameter of the memory hole is for example 70 nm, and a film thickness of the channel layer 44B is for example 8 nm. Moreover, regarding a film thickness of each layer of the memory gate insulating layer 43, that of the tunnel insulating film 43A is set to 5 nm, that of the first charge storage film 43B is set to 3 nm, that of the second charge storage film 43C is set to 5 nm, and that of the block insulating film 43D is set to 6 nm.

A dipole is formed at an interface between the high-dielectric constant insulating film 43E formed by alumina (Al₂O₃) and the block insulating film 43D formed by silicon oxide (SiO₂), whereby a barrier height of a conduction band of the block insulating film 43D becomes higher. Therefore, a leak current passing through the block insulating film 43D is reduced, whereby write efficiency can be improved. As a result, it takes a higher voltage to reach write saturation, hence a maximum threshold voltage during the write operation can be increased. Conversely, focusing on high barrier characteristics of the block insulating film 43D, it also becomes possible to raise read disturb tolerance without degrading write efficiency by forming the tunnel insulating film 43A thicker than in the first embodiment and by forming the block insulating film 43D thinner than in the first embodiment. In either of the above cases, a threshold voltage window during the write operation in the memory transistor MTr of the second embodiment can be enlarged.

### Third Embodiment

FIG. 15 is a cross-sectional view showing a MONOS type memory cell according to the third embodiment. In the memory transistor MTr of the present embodiment, a silicon microcrystalline film 43A′ is provided in an outer peripheral portion of the tunnel insulating film 43A. Silicon microcrystallines are formed within the tunnel insulating film 43A in the vicinity of the first charge storage film 43B. This silicon microcrystalline film 43A′ is formed by for example forming silicon on an outer periphery of the tunnel insulating film 43A and then annealing, and has a film thickness of about 1-2 nm.

The diameter of the memory hole is for example 70 nm, and a film thickness of the channel layer 44B is for example 7 nm. Regarding a film thickness of each layer of the memory gate insulating layer 43, that of the tunnel insulating film 43A including the silicon microcrystalline film 43A′ is set to 4 nm, that of the first charge storage film 43B is set to 3 nm, that of the second charge storage film 43C is set to 6 nm, and that of the block insulating film 43D is set to 8 nm.

The outer peripheral portion of the tunnel insulating film 43A is provided with the silicon microcrystalline film 43A′ to increase probability of electron injection via quantum mechanical effect. This makes it easier for electrons trapped in the second charge storage film 43C to pass into the channel layer 44B during the erase operation. As a result, the erase operation due to an electron current can be performed even more efficiently and erase operation time can be reduced.

### Fourth Embodiment

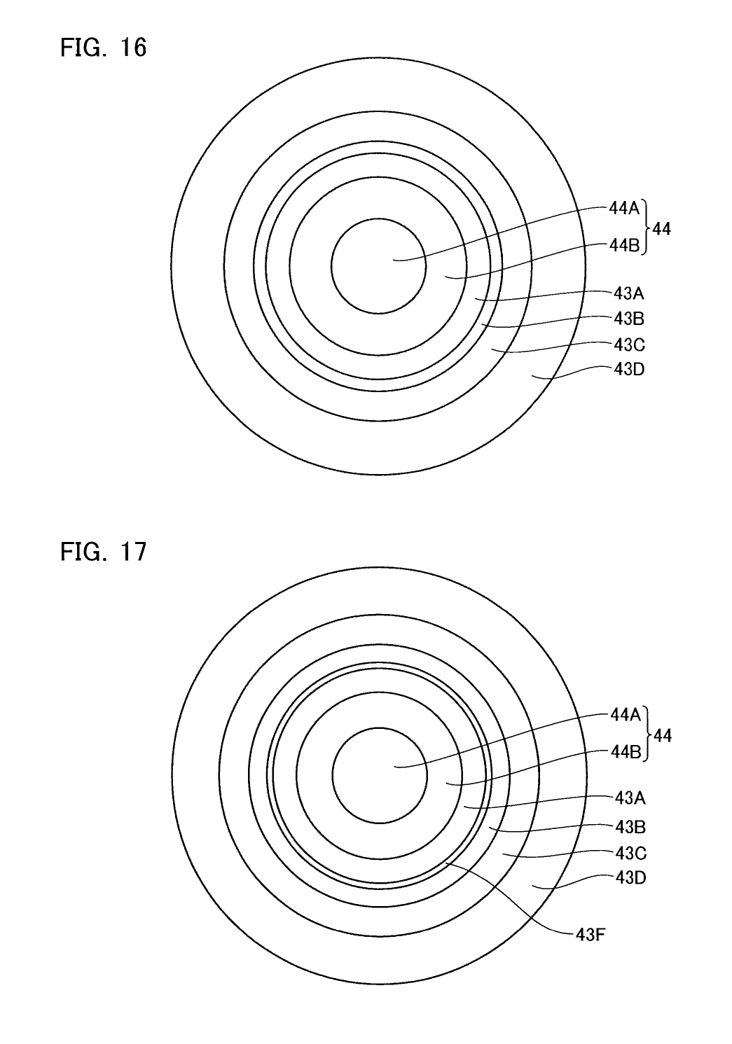

FIG. 16 is a cross-sectional view showing a MONOS type memory cell according to the fourth embodiment. In the memory transistor MTr of the present embodiment, the tunnel insulating film 43A is formed by a silicon oxynitride film (SiON). Moreover, a nitrogen concentration in this tunnel insulating film 43A is formed to become gradually higher as an outer peripheral portion of the tunnel insulating film 43A is approached.

In addition, a diameter of the memory hole is for example 70 nm, and a film thickness of the channel layer 44B is for example 7 nm. Moreover, regarding a film thickness of each layer of the memory gate insulating layer 43, that of the tunnel insulating film 43A is set to 4 nm, that of the first charge storage film 43B is set to 2 nm, that of the second charge storage film 43C is set to 5 nm, and that of the block insulating film 43D is set to 9 nm.

Configuring the nitrogen concentration in the tunnel insulating film 43A to become gradually higher as the outer peripheral portion of the tunnel insulating film 43A is approached results in the band gap of the tunnel insulating film 43A becoming gradually smaller as the outer peripheral portion of the tunnel insulating film 43A is approached. This makes it easier for electrons trapped in the second charge storage film 43C to pass into the channel layer 44B during the erase operation. As a result, the erase operation due to an electron current can be performed even more efficiently and erase operation time can be reduced.

### Fifth Embodiment

FIG. 17 is a cross-sectional view showing a MONOS type memory cell according to the fifth embodiment. In the memory transistor MTr of the present embodiment, a high-dielectric constant insulating film (high-k film) 43F is provided between the first charge storage film 43B and the tunnel insulating film 43A. This high-dielectric constant insulating film 43F is formed by for example alumina (Al₂O₃) and has a film thickness set at about 1 nm.

In addition, a diameter of the memory hole is for example 70 nm, and a film thickness of the channel layer 44B is for example 6 nm. Moreover, regarding a film thickness of each layer of the memory gate insulating layer 43, that of the tunnel insulating film 43A is set to 4 nm, that of the first charge storage film 43B is set to 3 nm, that of the second charge storage film 43C is set to 5 nm, and that of the block insulating film 43D is set to 8 nm.

Providing the high-dielectric constant insulating film 43F formed by alumina (Al₂O₃) between the first charge storage film 43B and the tunnel insulating film 43A makes it possible to prevent electrons escaping from the second charge storage film 43C and the first charge storage film 43B during a low electric field. As a result, data do not change by electrons being released from the second charge storage film 43C and the first charge storage film 43B during a low electric field (during non-operation), hence retention characteristics of the memory transistor MTr can be improved.

### Sixth Embodiment

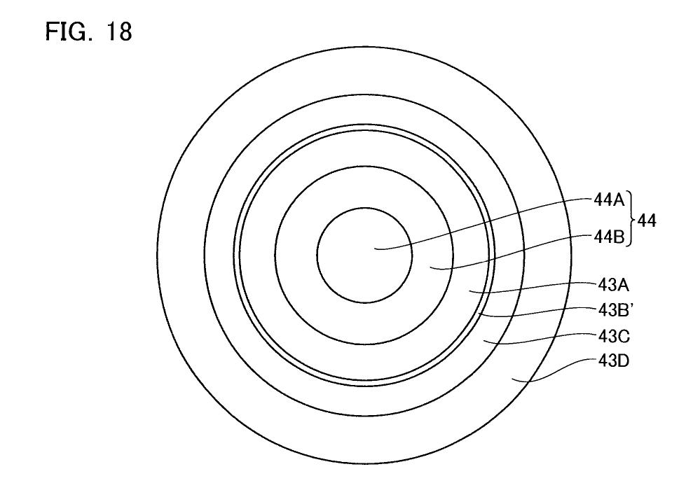

FIG. 18 is a cross-sectional view showing a MONOS type memory cell according to the sixth embodiment. In the above-described embodiments, polysilicon was employed as a material of the first charge storage film 43B. In contrast, in the memory transistor MTr of the present embodiment, a metal film is employed as a first charge storage film 43B′. This first charge storage film 43B′ is formed by for example titanium nitride (TiN) and has a film thickness set at about 1 nm. Moreover, a simple metal or a material including a metal compound may be employed as the metal film. That is, a metal and a metal compound (metal nitride, metal silicide, metal carbide, and so on) with conductivity and having free electrons may be widely used.

In addition, a diameter of the memory hole is for example 70 nm, and a film thickness of the channel layer 44B is for example 7 nm. Moreover, regarding a film thickness of each layer of the memory gate insulating layer 43, that of the tunnel insulating film 43A is set to 6 nm, that of the second charge storage film 43C is set to 5 nm, and that of the block insulating film 43D is set to 8 nm.

In the erase operation, electrons trapped in the second charge storage film 43C, after being emitted to the first charge storage film 43B, pass through the tunnel insulating film 43A to flow into the channel layer 44B, when the first charge storage film 43B′ formed by titanium nitride (TiN) is provided, as well. Moreover, since the erasure of electrons trapped in the second charge storage film 43C is performed by both hole injection and electron current, time taken for the erase operation can be reduced and a contribution can be made to improving erase characteristics.

In addition, since a metal material is employed as the first charge storage film 43B′, the first charge storage film 43B′ can be made thinner than the first charge storage film 43B of the first embodiment. To the extent that the first charge storage film 43B′ has been made thinner, the tunnel insulating film 43A or the block insulating film 43D can be formed thicker, whereby data retention characteristics of the memory transistor MTr can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the embodiments showed an example where the first charge storage film 43B is formed by polysilicon. This polysilicon may be doped with an impurity. For example, it is possible to form the first charge storage film 43B by polysilicon and dope said film with boron (B). This results in a minus charge of an acceptor (boron) existing in this p type doped first charge storage film 43B. In this case, since electrons trapped in the second charge storage film 43C and the minus charge of the first charge storage film 43B repel during data retention, movement of electrons from the second charge storage film 43C to the first charge storage 43B is suppressed, whereby data retention characteristics can be improved.

On the other hand, it is also possible to form the first charge storage film 43B by polysilicon and dope said film with phosphorus (P). This results in a plus charge of a donor (phosphorus) existing in this n type doped first charge storage film 43B. In this case, since a force is generated in a direction drawing out electrons present in the second charge storage film 43C into the first charge storage film 43B during data erase, movement of electrons from the second charge storage film 43C to the first charge storage 43B is promoted, whereby time taken for the erase operation due to an electron current can be further reduced. Note that whether to dope with an impurity or not, or what kind of impurity to dope with can be changed arbitrarily according to performance required of the memory transistor MTr.

What is claimed is:

1. A nonvolatile semiconductor memory device, comprising:
a memory string having a plurality of electrically rewritable memory transistors connected in series therein,
the memory string comprising:
a first semiconductor layer including a columnar portion extending in a perpendicular direction to a substrate, the first semiconductor layer functioning as a body of the memory transistor;
a tunnel insulating film formed surrounding a side surface of the columnar portion;
a charge storage film formed surrounding the tunnel insulating film and configured to be capable of storing a charge;
a block insulating film formed surrounding the charge storage film; and
a plurality of first conductive layers formed surrounding the block insulating film and disposed with a certain spacing along the perpendicular direction, and
the charge storage film comprising:
a first charge storage film having a conducting property and located in contact with the tunnel insulating film; and
a second charge storage film having an insulating property and formed between the first charge storage film and the block insulating film.

2. The nonvolatile semiconductor memory device according to claim 1, wherein
the first charge storage film is disposed only at a portion facing the first conductive layer.

3. The nonvolatile semiconductor memory device according to claim 1, wherein
a film thickness of the first charge storage film is thinner than a film thickness of the second charge storage film.

4. The nonvolatile semiconductor memory device according to claim 1, wherein
the first charge storage film is formed by a silicon film.

5. The nonvolatile semiconductor memory device according to claim 1, wherein
the first charge storage film is formed by a metal film.

6. The nonvolatile semiconductor memory device according to claim 1, wherein
the second charge storage film is formed by a silicon nitride film.

7. The nonvolatile semiconductor memory device according to claim 1, further comprising a high-dielectric constant insulating film formed between the second charge storage film and the block insulating film.

8. The nonvolatile semiconductor memory device according to claim 1, further comprising a high-dielectric constant insulating film formed between the block insulating film and the first conductive layer.

9. The nonvolatile semiconductor memory device according to claim 1, further comprising silicon microcrystallines within the tunnel insulating film in the vicinity of the first charge storage film.

10. The nonvolatile semiconductor memory device according to claim 1, wherein
the tunnel insulating film is formed by a silicon oxynitride film, and
a nitrogen concentration of the tunnel insulating film becomes gradually higher in a direction from the first semiconductor layer to the first charge storage film.

11. The nonvolatile semiconductor memory device according to claim 1, further comprising a high-dielectric constant insulating film formed between the first charge storage film and the tunnel insulating film.

12. The nonvolatile semiconductor memory device according to claim 1, wherein
the first semiconductor layer comprises a joining portion configured to join lower ends of a pair of columnar portions.

13. A nonvolatile semiconductor memory device, comprising:
a plurality of memory blocks each including a plurality of cell units and each representing a minimum unit of an erase operation;
a first line commonly provided to a plurality of the memory blocks and connected to one end of a plurality of the cell units;
a second line connected to the other end of a plurality of the cell units; and
a control circuit configured to control a voltage applied to a plurality of the memory blocks,
a plurality of the cell units each comprising:
a memory string having a plurality of electrically rewritable memory transistors connected in series therein;
a first transistor provided between one end of the memory string and the first line; and
a second transistor provided between the other end of the memory string and the second line,
the memory string comprising:
a first semiconductor layer including a columnar portion extending in a perpendicular direction to a substrate, the first semiconductor layer functioning as a body of the memory transistor;
a tunnel insulating film formed surrounding a side surface of the columnar portion;
a charge storage film formed surrounding the tunnel insulating film and configured to be capable of storing a charge;
a block insulating film formed surrounding the charge storage film; and
a plurality of first conductive layers formed surrounding the block insulating film and disposed with a certain spacing along the perpendicular direction, and
the charge storage film comprising:
a first charge storage film having a conducting property and located in contact with the tunnel insulating film; and
a second charge storage film having an insulating property and formed between the first charge storage film and the block insulating film, and
the control circuit, during the erase operation,
in a selected memory block, configured to set a voltage of the first line higher than a voltage of a gate of the first transistor by an amount of a first voltage to generate a gate-induced drain leakage current thereby raising a voltage of a body of the memory transistor, and configured to set a voltage of a gate of the memory transistor lower than the voltage of the body of the memory transistor to extract electrons from the second charge storage film thereby executing the erase operation on the selected memory block.

14. The nonvolatile semiconductor memory device according to claim 13, wherein
the control circuit, during a write operation for writing data to the memory transistor,
is configured to set the second transistor included in a selected cell unit to a conductive state,
is configured to charge the voltage of the body of the memory transistor included in the selected cell unit, and
is configured to set the first transistor included in the selected cell unit to a conductive state and set a gate of a selected memory transistor to a write voltage.

15. The nonvolatile semiconductor memory device according to claim 13, wherein
the first charge storage film is disposed only at a portion facing the first conductive layer.

16. The nonvolatile semiconductor memory device according to claim 13, wherein
a film thickness of the first charge storage film is thinner than a film thickness of the second charge storage film.

17. The nonvolatile semiconductor memory device according to claim 13, wherein
the first charge storage film is formed by a silicon film.

18. The nonvolatile semiconductor memory device according to claim 13, wherein
the first charge storage film is formed by a metal film.

19. The nonvolatile semiconductor memory device according to claim 13, wherein
the second charge storage film is formed by a silicon nitride film.
